(19) United States
(12) Patent Application Publication
(10) Pub. No.: US 2025/0301110 A1
(43) Pub. Date: Sep. 25, 2025

(54) LIGHT VALVE MODULE AND PROJECTION DEVICE

(71) Applicant: Coretronic Corporation, Hsin-Chu (TW)

(72) Inventors: Shih-Yao LI, Hsin-Chu (TW); Wen-Hao CHU, Hsin-Chu (TW); Chun-Lung YEN, Hsin-Chu (TW)

(21) Appl. No.: 19/075,697

(22) Filed: Mar. 10, 2025

(30) Foreign Application Priority Data
Mar. 19, 2024 (CN) 202410310536.7

(51) Int. Cl. H04N 9/31; H05K 7/20

(52) U.S. Cl. CPC H04N 9/3197; H04N 9/3144; H05K 7/205

(57) ABSTRACT

A light valve module and a projection device with the light valve module are provided. The light valve module includes a light valve, an interposer substrate, a thermal conductive component, and a flexible circuit board. The light valve includes a connection surface with a heat dissipation region and an electrical connection region. The interposer substrate includes a first surface and a second surface. The interposer substrate is disposed on the connection surface and is electrically connected to the at least one light valve by the first surface. The thermal conductive component is adjacently disposed with the interposer substrate and has a thermal conductive surface which is attached to the heat dissipation region. The flexible circuit board is disposed on the interposer substrate and the thermal conductive component, and the interposer substrate is electrically connected to the flexible circuit board by the second surface.

### CROSS REFERENCE TO RELATED APPLICATION

This application claims the priority benefit of Chinese Patent Application Serial Number 202410310536.7, filed on Mar. 19, 2024, the full disclosure of which is incorporated herein by reference.

### BACKGROUND

### Technical Field

The present disclosure is related to a light valve module and a projection device and is particularly related to the light valve module and the projection device with the light valve module.

### Related Art

DLP is a display technology used in a projector and a rear projection television. In the DLP projector, an image is generated by a DMD. The DMD is a microlens array which is arranged on a semiconductor chip and is constituted by a plurality of accurate microlenses, and each of the plurality of microlenses controls one pixel in a projected scene. The number of the plurality of microlenses corresponds to the resolution of the projected scene.

The assembly in the rear of the DMD is constructed by sequentially mounting a connector, a flexible circuit board, a clamp and a heat dissipation component and a part where a heat source mainly generates is the rear of the DMD connected to the connector, the heat dissipation component has a boss, and the boss penetrates the structure of the connector, the flexible circuit board and the clamp so that the boss of the heat dissipation component can directly contact the position where the heat source generates to achieve heat dissipation effects. However, because the boss is limited to the aforementioned condition, the structure of the boss is small and the area where the boss directly contacts the rear of the DMD is also small, and it is difficult to meet the requirements of the heat dissipation.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The present disclosure provides a light valve module which improves mounting of a heat dissipation component to facilitate heat dissipation effects more.

The present disclosure further provides a projection device which includes the aforementioned light valve module and has great heat dissipation effects.

Other objectives, features and advantages of the present disclosure will be further understood from the further technological features disclosed by the embodiments of the present disclosure wherein there are shown and described preferred embodiments of the present disclosure, simply by way of illustration of modes best suited to carry out the disclosure.

In order to achieve one, one part or all of the objectives, the light valve module in one embodiment of the present disclosure includes at least one light valve, an interposer substrate, a thermal conductive component, and a flexible circuit board. The at least one light valve includes an image surface and a connection surface which are located on two relative sides of the at least one light valve, and the image surface is configured to generate an image light beam, and the connection surface includes a heat dissipation region and an electrical connection region adjacent to the heat dissipation region. The interposer substrate includes a first surface and a second surface which are relatively disposed to each other, and the interposer substrate is disposed on the connection surface of the at least one light valve by the first surface, and the first surface corresponds to the electrical connection region so that the interposer substrate is electrically connected to the at least one light valve. The thermal conductive component is adjacently disposed with the interposer substrate, and the thermal conductive surface of the thermal conductive component is attached to the heat dissipation region of the connection surface of the at least one light valve and is parallel to the connection surface. The flexible circuit board is disposed on the interposer substrate and the thermal conductive component, and the interposer substrate is electrically connected to the flexible circuit board by the second surface.

In order to achieve one, one part or all of the objectives, the projection device in one embodiment of the present disclosure includes a light source module, a light valve module and a lens module. The light source module is configured to provide an illumination light beam. The light valve module is located on the transmission path of the illumination light beam and includes at least one light valve, an interposer substrate, a thermal conductive component, and a flexible circuit board. The at least one light valve includes an image surface and a connection surface which are located on two relative sides of the at least one light valve. The image surface is configured to convert the illumination light beam into an image light beam, and the connection surface includes a heat dissipation region and an electrical connection region adjacent to the heat dissipation region. The interposer substrate includes a first surface and a second surface which are relatively disposed to each other, and the interposer substrate is disposed on the connection surface of the at least one light valve by the first surface, and the first surface corresponds to the electrical connection region so that the interposer substrate is electrically connected to the at least one light valve. The thermal conductive component is adjacently disposed with the interposer substrate, and the thermal conductive surface of the thermal conductive component is attached to the heat dissipation region of the connection surface of the at least one light valve and is parallel to the connection surface. The flexible circuit board is disposed on the interposer substrate and the thermal conductive component, and the interposer substrate is electrically connected to the flexible circuit board by the second surface. The lens module is disposed on the transmission path of the image light beam and is configured to project the image light beam outside the projection device.

In view of the above description, the present embodiments of the present disclosure have at least one of the following advantages or effects. In the configuration of the light valve module of the present disclosure, the thermal conductive component is adjacently disposed with the interposer substrate, and the thermal conductive surface of the thermal conductive component is attached to the heat dissipation region of the connection surface of the at least one light valve and is parallel to the connection surface. Thus, the thermal conductive surface of the thermal conductive component can directly contact the heat dissipation region of the light valve to effectively enhance the heat dissipation effects. In addition, the projection device utilizing the light valve module of the present disclosure may have the great heat dissipation effects.

### BRIEF DESCRIPTION OF THE DRAWINGS

The accompanying drawings herein is provided to have a further understanding on the present disclosure and constitutes one part of the present disclosure. The schematic embodiments and the description of the present disclosure is used to explain the present disclosure instead of constituting inappropriate limitation. In the drawings:

FIG. 1 depicts a block diagram of a projection device according to one embodiment of the present disclosure.

FIG. 2 depicts an exploded view diagram of a light valve module of a projection device according to one embodiment of the present disclosure.

FIG. 3 depicts the further exploded view diagram of the light valve module of the projection device of FIG. 2.

FIG. 4 depicts the schematic diagram of the light valve module of FIG. 2.

FIG. 5 depicts the exploded view diagram of the light valve module of FIG. 4.

FIG. 6 depicts the cross diagram sectioning the light valve module along the A-A′ line of FIG. 4.

FIG. 7 depicts a schematic diagram of a light valve module according to another embodiment of the present disclosure.

FIG. 8 depicts the exploded view diagram of the light valve module of FIG. 7.

FIG. 9 depicts a schematic diagram of a light valve module according to yet another embodiment of the present disclosure.

FIG. 10 depicts the exploded view diagram of the light valve module of FIG. 9.

FIG. 11 depicts a schematic diagram of a fixing component of a light valve module according to one embodiment of the present disclosure.

FIG. 12 depicts a schematic diagram of a thermal conductive component of a light valve module according to one embodiment of the present disclosure.

### DETAILED DESCRIPTION OF THE EMBODIMENTS

In the following detailed description of the preferred embodiments, reference is made to the accompanying drawings which form a part hereof, and in which are shown by way of illustration specific embodiments in which the present disclosure may be practiced. In this regard, directional terminology, such as “top,” “bottom,” “front,” “back,” etc., is used with reference to the orientation of the Figure(s) being described. The components of the present disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

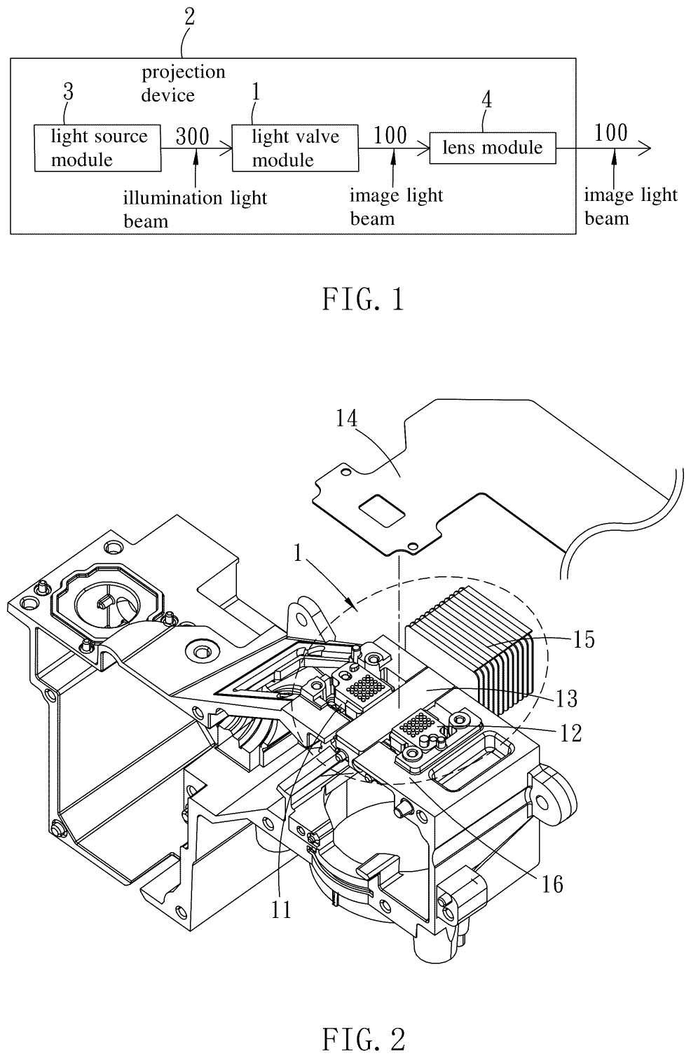

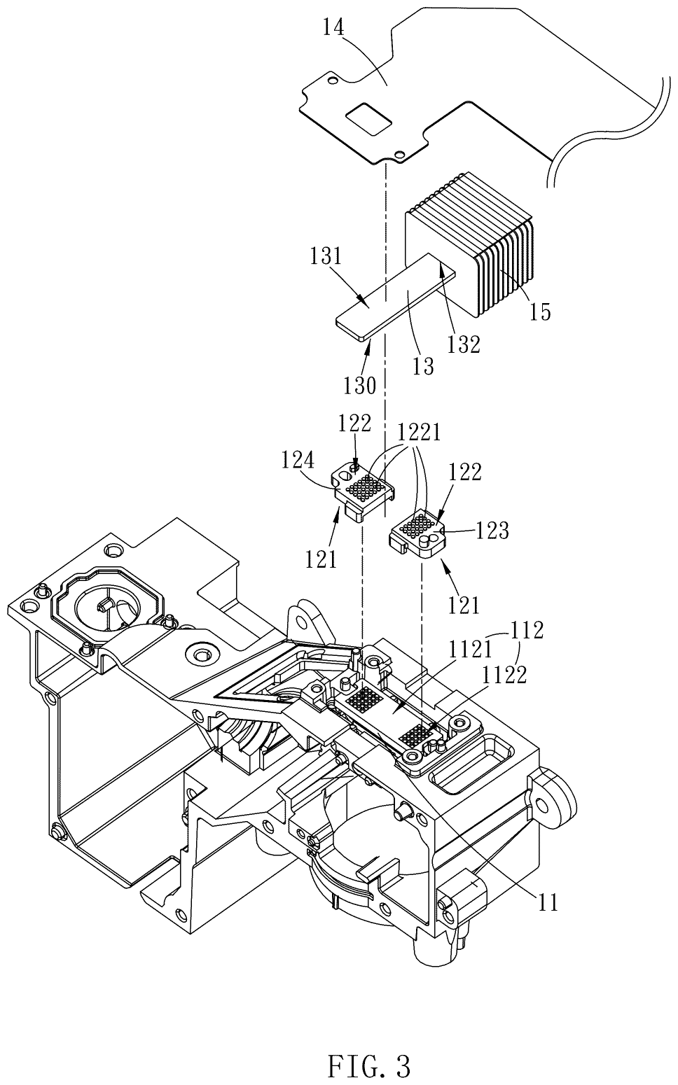

Please refer to FIG. 1 to FIG. 3, wherein FIG. 1 depicts a block diagram of a projection device according to one embodiment of the present disclosure, FIG. 2 depicts an exploded view diagram of a light valve module, and FIG. 3 depicts the further exploded view diagram of the light valve module of the projection device of FIG. 2. As shown in the figures, the present embodiment provides a light valve module 1 (i.e., the position denoted by the dotted line in FIG. 2) including at least one light valve 11, an interposer substrate 12 (an interposer/a connector), a thermal conductive component 13 and a flexible circuit board 14. The at least one light valve 11 includes an image surface 111 (shown in FIG. 5) and a connection surface 112 which are located on two relative sides of the at least one light valve 11. The image surface 111 is configured to generate an image light beam 100, and specifically, the image surface 111 is configured to convert an illumination light beam 300 into the image light beam 100; the connection surface 112 includes a heat dissipation region 1121 and an electrical connection region 1122 adjacent to the heat dissipation region 1121. The interposer substrate 12 includes a first surface 121 and a second surface 122 which are relatively disposed to each other, and the interposer substrate 12 is disposed on the connection surface 112 of the at least one light valve 11 by the first surface 121, and the first surface 121 corresponds to the electrical connection region 1122 so that the interposer substrate 12 is electrically connected to the at least one light valve 11. The thermal conductive component 13 is adjacently disposed with the interposer substrate 12, and the thermal conductive surface 130 of the thermal conductive component 13 is attached to the heat dissipation region 1121 of the connection surface 112 of the at least one light valve 11 and is parallel to the connection surface 112. The flexible circuit board 14 is disposed on the interposer substrate 12 and the thermal conductive component 13, and the interposer substrate 12 is electrically connected to the flexible circuit board 14 by the second surface 122.

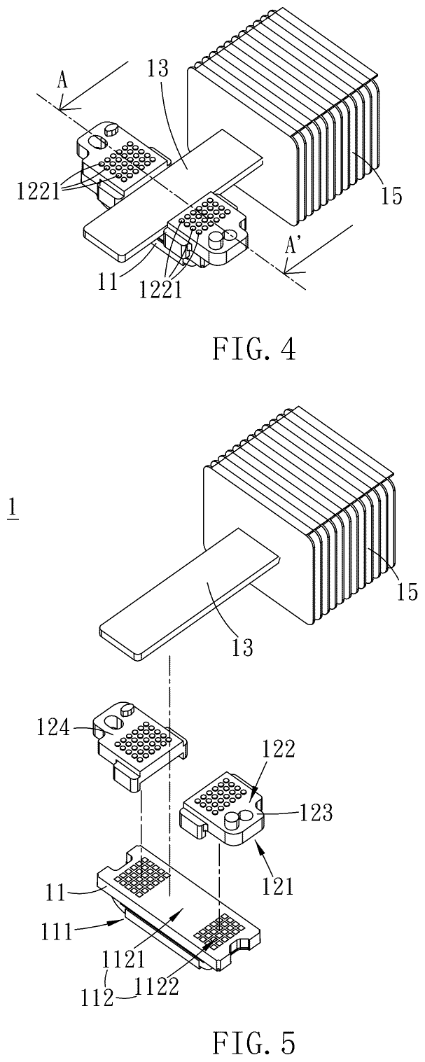

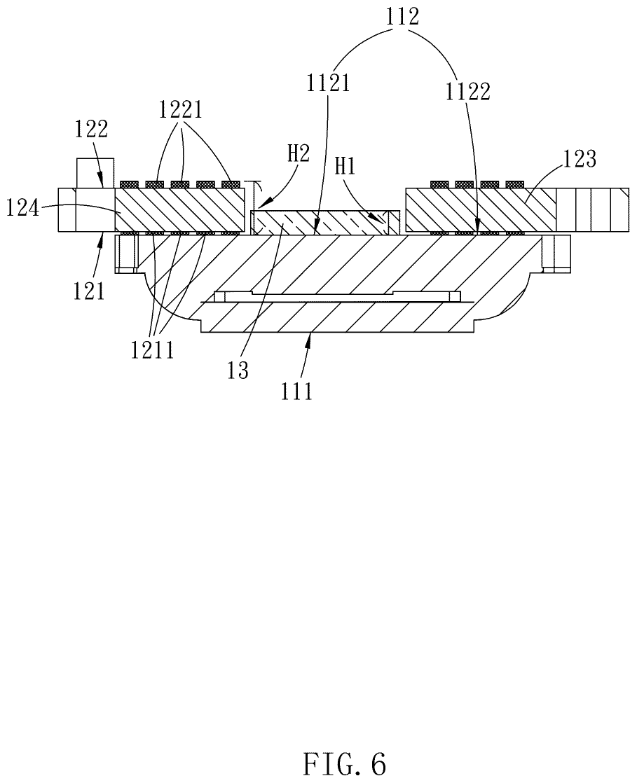

Please refer to FIG. 4 to FIG. 6, wherein FIG. 4 depicts the schematic diagram of the light valve module of FIG. 2, FIG. 5 depicts the exploded view diagram of the light valve module of FIG. 4 and FIG. 6 depicts the cross diagram sectioning the light valve module along the A-A′ line of FIG. 4. As shown in the figures, the number of the electrical connection regions 1122 of the connection surface 112 of the at least one light valve 11 in the present embodiment is two, and the two electrical connection regions 1122 are respectively located on two relative sides of the heat dissipation region 1121. The interposer substrate 12 includes a first interposer part 123 and a second interposer part 124, the first interposer part 123 and the second interposer part 124 are correspondingly disposed with the two electrical connection regions 1122, and the thermal conductive component 13 is correspondingly disposed with the heat dissipation region 1121; in other words, the thermal conductive component 13 is located between the first interposer part 123 and the second interposer part 124. The first interposer part 123 and the second interposer part 124 in the present embodiment are two separate elements, and the first interposer part 123 and the second interposer part 124 are located on two sides of the thermal conductive component 13.

In the present embodiment, the light valve module 1 further includes a heat dissipation component 15, the first part 131 of the thermal conductive component 13 contacts and is connected to the connection surface 112 of the at least one light valve 11, and the second part 132 of the thermal conductive component 13 is connected to the heat dissipation component 15 (please refer to FIG. 3). The thermal conductive component 13 is a flat heat pipe structure, and the flat heat pipe structure is beneficial to attach to the connection surface 112 of the at least one light valve 11 and to increase the contact area between the thermal conductive component 13 and the connection surface 112 in order to enhance thermal contact conductance benefits. Specifically, the thermal conductive component 13 of the light valve module 1 in the present embodiment of the present disclosure does not have any boss, and the heat dissipation region 1121 may extend to the edges of the two relative sides of the connection surface 112. When the interposer substrate 12 is configured on the electrical connection region 1122 of the light valve 11, the interposer substrate 12 does not contact the heat dissipation region 1121 of the light valve 11, and the entire heat dissipation region 1121 is exposed, and thus, the thermal conductive surface 130 of the thermal conductive component 13 may be attached to the entire heat dissipation region 1121 of the connection surface 112 of the light valve 11. Preferably, when the thermal conductive surface 130 of the thermal conductive component 13 contacts the heat dissipation region 1121 of the connection surface 112, the entire heat dissipation region 1121 is covered by one part of the thermal conductive surface 130, but the other part of the thermal conductive surface 130 does not contact the heat dissipation region 1121. In comparison with that the connector has an opening hiding the edges on the two relative sides of the connection surface of the light valve and being correspondingly disposed with the boss of the heat dissipation component in the prior art, the present embodiment may increase the area of the heat dissipation region 1121 (i.e., the contact area between the heat dissipation region 1121 and the thermal conductive surface 130 of the thermal conductive component 13) to further enhance thermal conductance efficiency.

In the present embodiment, the thermal conductive component 13 may be a heat pipe, a vapor chamber, etc., which are manufactured by solid materials with high thermal conductivity such as Cu, Al, graphene, or composite material (e.g., heat dissipation materials with nanoparticles) or a two-phase thermal conductance assembly. The aforementioned thermal conductive component 13 may be selected according to user requirements. After the first part 131 of the thermal conductive component 13 absorbs the heat of the connection surface 112 of the light valve 11, the heat is transferred to the second part 132 by the thermal conductive component 13 and is dissipated by the heat dissipation component 15 connected to the second part 132 of the thermal conductive component 13, and the heat dissipation component 15 is a heat dissipation fin structure. Specifically, the heat absorbed by the thermal conductive component 13 is transferred from the first part 131 to the second part 132 along a direction parallel to the thermal conductive surface 130 (or the connection surface 112 of the light valve 11).

In addition, in the other embodiments, the thermal conductive component 13 may directly serve as the thermal paste to conduct the heat, and the connection surface 112 of the at least one light valve 11 is coated with the thermal paste, and the heat dissipation component 15 is further disposed to contact the thermal paste, and similarly, it may achieve heat dissipation effects. Besides, in the other embodiments, the thermal conductive component 13 may be also serve as the heat pipe and the thermal paste at the same time, and the heat dissipation region 1121 of the connection surface 112 of the at least one light valve 11 is coated with the thermal paste, and the heat pipe is further disposed on the thermal paste, and the heat dissipation component 15 is disposed at one terminal of the heat pipe. The aforementioned embodiments are merely examples for explanations and are not limited thereto.

Please refer to FIG. 4 and FIG. 6 again. In the present embodiment, the first surface 121 of the interposer substrate 12 includes a plurality of first metal pins 1211, and the second surface 122 of the interposer substrate 12 has a plurality of second metal pins 1221. The plurality of first metal pins 1211 and the plurality of second metal pins 1221 may be vertically disposed or be slantwise disposed on the connection surface 112, and the above corresponding disposal of the first metal pins 1211 and the second metal pins 1221 are merely examples for explanations and are not limited thereto. The plurality of first metal pins 1211 of the first surface 121 is configured to be electrically connected to the electrical connection region 1122 of the connection surface 112 of the at least one light valve 11, and the plurality of second metal pins 1221 of the second surface 122 is configured to be electrically connected to the flexible circuit board 14. The thermal conductive component 13 has a thickness H1 on a thickness direction vertical to the connection surface 112, and the thickness H1 of the thermal conductive component 13 is less than or equal to the distance H2 between each of the plurality of first metal pins 1211 and the corresponding second metal pin 1221.

According to the aforementioned description, the plurality of first metal pins 1211 and the plurality of second metal pins 1221 are expressed by disc structures, but the structures of the plurality of first metal pins 1211 and the plurality of second metal pins 1221 are not limited thereto. The plurality of first metal pins 1211 and the plurality of second metal pins 1221 are compressible elastic components. When the interposer substrate 12 is electrically connected to the at least one light valve 11 and the flexible circuit board 14, the plurality of first metal pins 1211 are compressed to approach the first surface 121 (the plurality of first metal pins 1211 as shown in FIG. 6 reveal a compressed state), and there is a thickness gap of the compressed first metal pin 1211 between the first surface 121 and the connection surface 112, and similarly, the plurality of second metal pins 1221 are compressed to approach the second surface 122. In other words, the distance H2 between each of the plurality of first metal pins 1211 and the corresponding second metal pin 1221 is close to the distance between the first surface 121 and the second surface 122 when compressed. In the present embodiment, when the thickness H1 of the thermal conductive component 13 is less than the distance H2 between each of the plurality of first metal pins 1211 and the corresponding second metal pin 1221, the thermal conductive component 13 is disposed within the interposer substrate 12, and it may avoid the thickness H1 of the thermal conductive component 13 from affecting the two surfaces (i.e., the first surface 121 and the second surface 122) of the interposer substrate 12 to be electrically connected to the at least one light valve 11 and the flexible circuit board 14. When the thickness H1 of the thermal conductive component 13 is equal to the distance H2 between each of the plurality of first metal pins 1211 and the corresponding second metal pin 1221, the thermal conductive component 13 is disposed within the interposer substrate 12, and the thermal conductive component 13 may be fixed in the interposer substrate 12 by the at least one light valve 11 and the flexible circuit board 14.

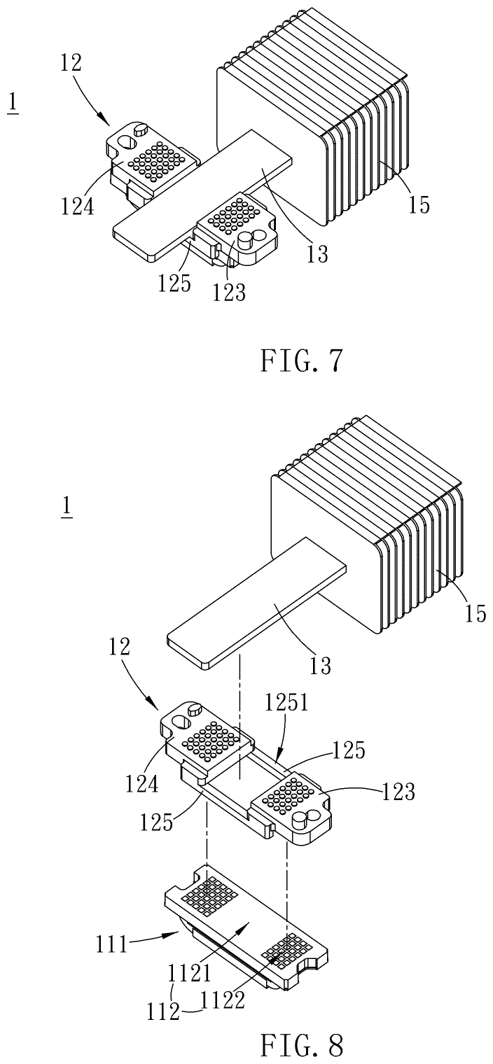

Please refer to FIG. 7 and FIG. 8, wherein FIG. 7 depicts a schematic diagram of a light valve module according to another embodiment of the present disclosure and FIG. 8 depicts the exploded view diagram of the light valve module of FIG. 7. As shown in the figures, the interposer substrate 12 in the present embodiment has a bridge part 125 connected between the first interposer part 123 and the second interposer part 124, and the bridge surface 1251 of the bridge part 125 is even with or is lower than the connection surface 112 (i.e., the surface of the heat dissipation region 1121). In the present embodiment, the number of the bridge parts 125 is two, the two bridge parts 125 are located on two sides of the at least one light valve 11 and is beneficial to limit and fix the interposer substrate 12 on the at least one light valve 11 in order to strengthen the combination intensity between the interposer substrate 12 and the at least one light valve 11. Because the bridge surface 1251 of the bridge part 125 in the present embodiment is even with or is lower than the connection surface 112, the interposer substrate 12 does not contact the heat dissipation region 1121 of the light valve 11 and the entire heat dissipation region 1121 is exposed when the interposer substrate 12 is configured on the electrical connection region 1122 of the light valve 11. Hence, the thermal conductive surface 130 of the thermal conductive component 13 may be attached to the entire heat dissipation region 1121 of the connection surface 112 of the light valve 11, the entire heat dissipation region 1121 is covered by one part of the thermal conductive surface 130 and the other part of the thermal conductive surface 130 does not contact the heat dissipation region 1121. By the aforementioned configuration, the area of the heat dissipation region 1121 (i.e., the contact area between the heat dissipation region 1121 and the thermal conductive surface 130 of the thermal conductive component 13) may be increased to further enhance the thermal conductance efficiency.

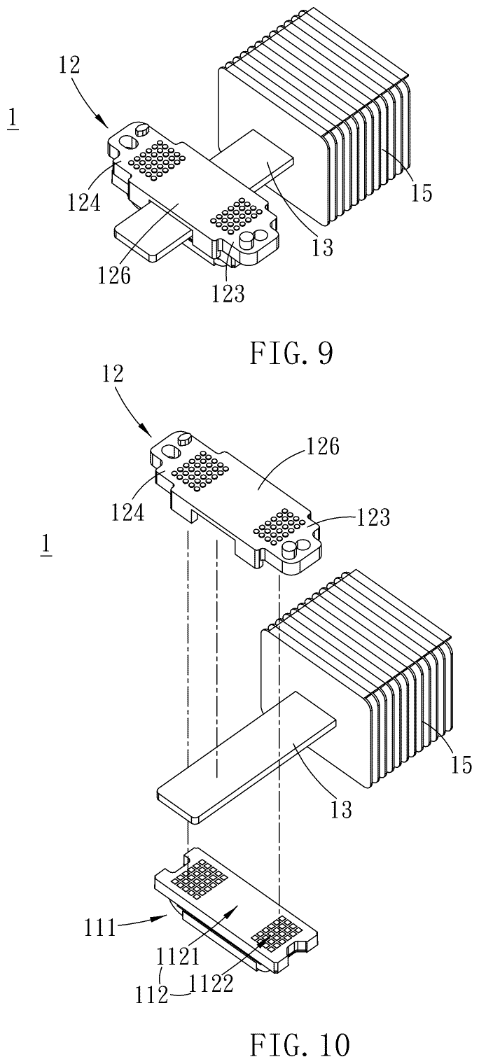

Please refer to FIG. 9 and FIG. 10, wherein FIG. 9 depicts a schematic diagram of a light valve module according to yet another embodiment of the present disclosure and FIG. 10 depicts the exploded view diagram of the light valve module of FIG. 9. As shown in the figures, the interposer substrate 12 in the present embodiment has a bridge part 126 connected between the first interposer part 123 and the second interposer part 124, and the bridge part 126 partially covers the thermal conductive component 13. The bridge part 126 is beneficial to fix the thermal conductive component 13 in the at least one light valve 11 and the interposer substrate 12. Because the bridge part 126 in the present embodiment partially covers the thermal conductive component 13, the interposer substrate 12 does not contact the heat dissipation region 1121 of the light valve 11 when the interposer substrate 12 is configured on the electrical connection region 1122 of the light valve 11. Hence, the thermal conductive surface 130 of the thermal conductive component 13 may be attached to the entire heat dissipation region 1121 of the connection surface 112 of the light valve 11, the entire heat dissipation region 1121 is covered by one part of the thermal conductive surface 130 and the other part of the thermal conductive surface 130 does not contact the heat dissipation region 1121. By the aforementioned configuration, the area of the heat dissipation region 1121 (i.e., the contact area between the heat dissipation region 1121 and the thermal conductive surface 130 of the thermal conductive component 13) may be increased to further enhance the thermal conductance efficiency.

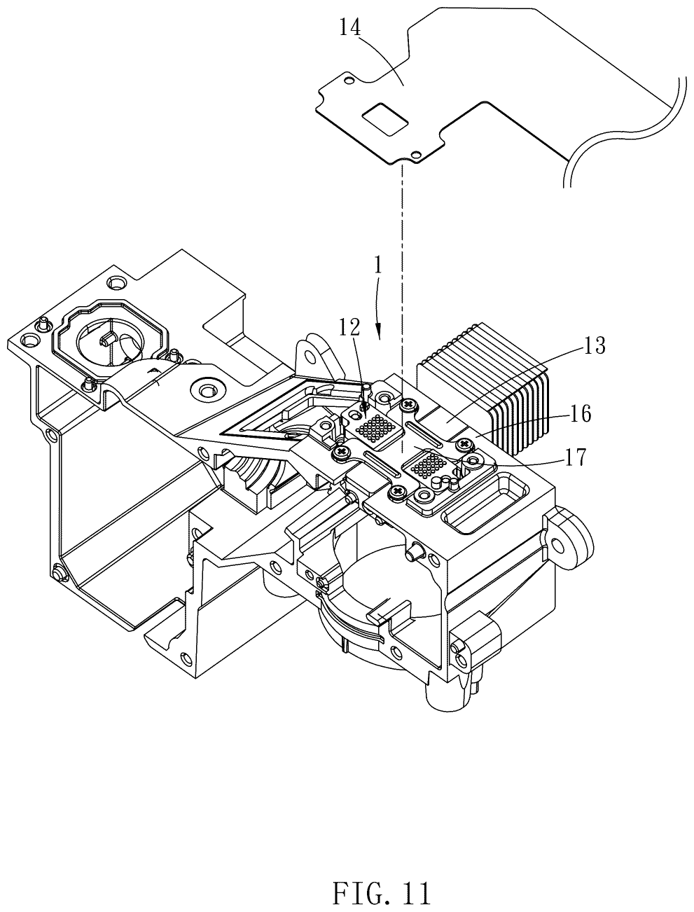

Please refer to FIG. 11, which depicts a schematic diagram of a fixing component of a light valve module according to one embodiment of the present disclosure. As shown in the figures, in the present embodiment, the light valve module 1 is adapted to be disposed on a case 16, and the light valve module 1 further includes a fixing component 17 disposed between the interposer substrate 12 and the flexible circuit board 14. The thermal conductive component 13 is adjacently fixed on the interposer substrate 12 and the heat dissipation region 1121 (please refer to FIG. 4 and FIG. 5 again) of the connection surface 112 of the at least one light valve 11 by fixing the fixing component 17 on the case 60, and the fixing component 17 is connected to the thermal conductive component 13, wherein the fixing component 17 may be fixed on the thermal conductive component 13 by welding or attaching. The fixing component 17 is an X-shaped or I-shaped spring latch structure to expose the second metal pins 1121 of the interposer substrate 12 so that the flexible circuit board 14 is electrically connected to the interposer substrate 12. At the same time, the fixing component 17 is located between the flexible circuit board 14 and the thermal conductive component 13 and may isolate the direct contact of the flexible circuit board 14 and the thermal conductive component 13 in order to avoid the heat of the thermal conductive component 13 from affecting the performance of the flexible circuit board 14. In the present embodiment, the four ends of the fixing component 17 is fixed on the case 16 by screws.

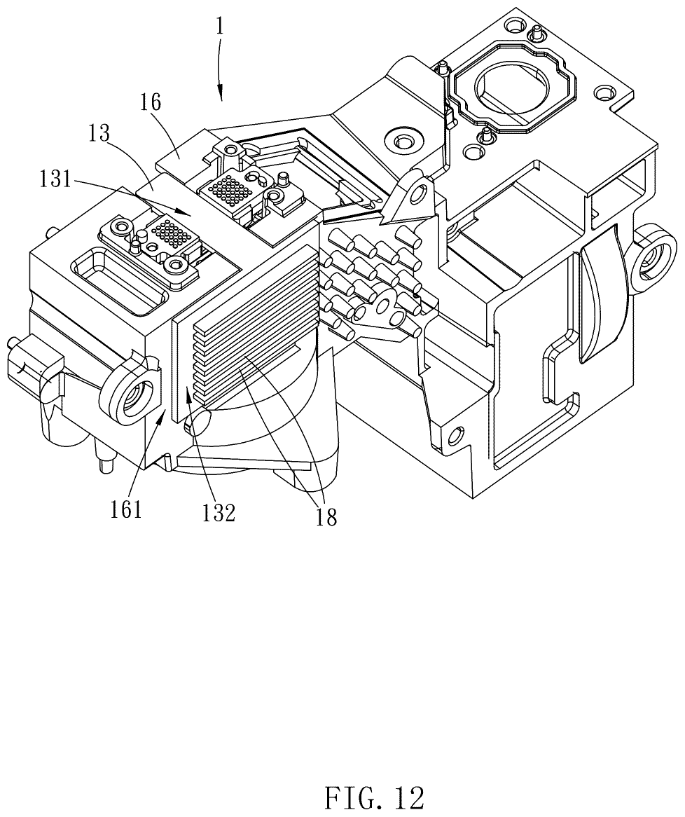

Please refer to FIG. 12, which depicts a schematic diagram of a thermal conductive component of a light valve module according to one embodiment of the present disclosure. As shown in the figures, in the present embodiment, the light valve module 1 is adapted to be disposed on the case 16, and the surface on one side of the case 16 has a low temperature surface 161. The first part 131 of the thermal conductive component 13 contacts and is connected to the connection surface 112 of the at least one light valve 11, and the second part 132 of the thermal conductive component 13 extends outwardly to the side surface of the case 16 so that the second part 132 of the thermal conductive component 13 is connected to the low temperature surface 161 of the case 16. In the present embodiment, the second part 132 of the thermal conductive component 13 may be further designed as heat transfer fins to enhance the heat dissipation efficiency of the second part 132 of the thermal conductive component 13.

Please refer to FIG. 1 to FIG. 3 again. The present embodiment provides a projection device 2 including a light source module 3, the light valve module 1 and the lens module 4. The light source module 3 is configured to provide an illumination light beam 300. The light valve module 1 is located on the transmission path of the illumination light beam 300 and includes the at least one light valve 11, the interposer substrate 12, the thermal conductive component 13, and the flexible circuit board 14. The at least one light valve 11 is configured to convert the illumination light beam 300 into an image light beam 100 and includes the image surface 111 and the connection surface 112 which are located on two relative sides of the at least one light valve 11. The image surface 111 is configured to generate the image light beam 100, and the connection surface 112 includes the heat dissipation region 1121 and the electrical connection region 1122 adjacent to the heat dissipation region 1121. The interposer substrate 12 includes the first surface 121 and the second surface 122 which are relatively disposed to each other, and the interposer substrate 12 is disposed on the connection surface 112 of the at least one light valve 11 by the first surface 121, and the first surface 121 corresponds to the electrical connection region 1122 so that the interposer substrate 12 is electrically connected to the at least one light valve 11. The thermal conductive component 13 is adjacently disposed with the interposer substrate 12, and the thermal conductive surface 130 of the thermal conductive component 13 is attached to the heat dissipation region 1121 of the connection surface 112 of the at least one light valve 11 and is parallel to the connection surface 112. The flexible circuit board 14 is disposed on the interposer substrate 12 and the thermal conductive component 13, and the interposer substrate 12 is electrically connected to the flexible circuit board 14 by the second surface 122. The lens module 4 is disposed on the transmission path of the image light beam 100 and is configured to project the image light beam 100 outside the projection device 2.

In the present embodiment, the number of light valve 11 in the light valve module 1 is one, but the present disclosure is not limited thereto; in the other embodiment, the number of the light valve 11 may be multiple. The light valve 11 may be the DMD. However, in the other embodiments, the light valve 11 may be a reflective light modulator such as a LCoS panel or may be a reflective liquid crystal panel or the other light beam modulator. The present disclosure does not limit the form and the type of the light valve 11. The light source module 3 is constituted by a combination of at least one or more light emission components, a wavelength converter, a light diffuser, a light filter and a number of light splitters. In the other embodiment, the light source module 3 is constituted by the combination of the number of light emission components with different light wavelengths and the number of light splitters for example. The light source module 3 is configured to provide and output the light with different light wavelengths to form the illumination light beam 300. However, the present disclosure does not limit the form and the type of the light source module 3. The lens module 4, for example, includes a combination of one or more optical lenses with different diopters. For example, the lens module 4 includes the various combinations of spherical lenses such as bi-concave spherical lenses, bi-convex spherical lenses, convex-concave spherical lenses, plano-convex spherical lenses, and plano-concave spherical lenses. In one embodiment, the lens module 4 may further include an optical flat lens, and the image light beam 100 from the light valve module 1 is projected onto a projection target. The present disclosure does not limit the form and the type of the lens module 4.

According to the above description, the present embodiments of the present disclosure have at least one of the following advantages or effects. In the configuration of the light valve module of the present disclosure, the thermal conductive component is adjacently disposed with the interposer substrate, and the thermal conductive surface of the thermal conductive component is attached to the heat dissipation region of the connection surface of the at least one light valve and is parallel to the connection surface. Thus, the thermal conductive surface of the thermal conductive component can directly contact the heat dissipation region of the light valve to effectively enhance the heat dissipation effects. In addition, the projection device utilizing the light valve module of the present disclosure may have the great heat dissipation effects.

The foregoing description of the preferred embodiments of the present disclosure has been presented for purposes of illustration and description. It is not intended to be exhaustive or to limit the present disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the present disclosure and its best mode practical application, thereby to enable persons skilled in the art to understand the present disclosure for various embodiments and with various modifications as are suited to the particular use or implementation contemplated. It is intended that the scope of the present disclosure be defined by the claims appended hereto and their equivalents in which all terms are meant in their broadest reasonable sense unless otherwise indicated. Therefore, the term “the disclosure”, “the present disclosure” or the like does not necessarily limit the claim scope to a specific embodiment, and the reference to particularly preferred exemplary embodiments of the present disclosure does not imply a limitation on the present disclosure, and no such limitation is to be inferred. The present disclosure is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the present disclosure. It should be appreciated that variations may be made in the embodiments described by persons skilled in the art without departing from the scope of the present disclosure as defined by the following claims. Moreover, no element and component in the present disclosure is intended to be dedicated to the public regardless of whether the element or component is explicitly recited in the following claims.

What is claimed is:

1. A light valve module comprising:
at least one light valve comprising an image surface and a connection surface which are located on two relative sides of the at least one light valve, wherein the image surface is configured to generate an image light beam, and the connection surface comprises a heat dissipation region and an electrical connection region adjacent to the heat dissipation region;
an interposer substrate comprising a first surface and a second surface which are relatively disposed to each other, wherein the interposer substrate is disposed on the connection surface of the at least one light valve by the first surface, and the first surface corresponds to the electrical connection region so that the interposer substrate is electrically connected to the at least one light valve;
a thermal conductive component adjacently disposed with the interposer substrate, wherein a thermal conductive surface of the thermal conductive component is attached to the heat dissipation region of the connection surface of the at least one light valve and is parallel to the connection surface; and
a flexible circuit board disposed on the interposer substrate and the thermal conductive component, wherein the interposer substrate is electrically connected to the flexible circuit board by the second surface.

2. The light valve module according to claim 1, wherein the first surface of the interposer substrate has a plurality of first metal pins, the second surface of the interposer substrate has a plurality of second metal pins, the thermal conductive component has a thickness on a thickness direction vertical to the connection surface, and the thickness of the thermal conductive component is less than or equal to a distance between each of the plurality of first metal pins and the corresponding second metal pin.

3. The light valve module according to claim 1, wherein a number of the electrical connection regions of the connection surface of the at least one light valve is two, the two electrical connection regions are respectively located on two relative sides of the heat dissipation region, the interposer substrate comprises a first interposer part and a second interposer part which are correspondingly disposed with the two electrical connection regions, and the thermal conductive component is located between the first interposer part and the second interposer part.

4. The light valve module according to claim 3, wherein the interposer substrate has a bridge part connected between the first interposer part and the second interposer part, and the bridge part partially covers the thermal conductive component.

5. The light valve module according to claim 3, wherein the interposer substrate has a bridge part connected between the first interposer part and the second interposer part, and a bridge surface of the bridge part is even with or is lower than the connection surface.

6. The light valve module according to claim 1, further comprising a heat dissipation component, wherein a first part of the thermal conductive component contacts and is connected to the connection surface, and a second part of the thermal conductive component is connected to the heat dissipation component.

7. The light valve module according to claim 1, wherein the light valve module is adapted to be disposed on a case, the light valve module further comprises a fixing component disposed between the interposer substrate and the flexible circuit board, the thermal conductive component is adjacently fixed on the interposer substrate and the heat dissipation region of the connection surface of the at least one light valve by fixing the fixing component on the case, and the fixing component is connected to the thermal conductive component.

8. The light valve module according to claim 7, wherein the fixing component is a spring latch.

9. The light valve module according to claim 7, wherein the thermal conductive component is at least one of a heat pipe, a vapor chamber, or thermal paste.

10. A projection device comprising:
a light source module configured to provide an illumination light beam;
a light valve module located on a transmission path of the illumination light beam and comprising:
at least one light valve comprising an image surface and a connection surface which are located on two relative sides of the at least one light valve, wherein the image surface is configured to convert the illumination light beam into an image light beam, and the connection surface comprises a heat dissipation region and an electrical connection region adjacent to the heat dissipation region;
an interposer substrate comprising a first surface and a second surface which are relatively disposed to each other, wherein the interposer substrate is disposed on the connection surface of the at least one light valve by the first surface, and the first surface corresponds to the electrical connection region so that the interposer substrate is electrically connected to the at least one light valve;
a thermal conductive component adjacently disposed with the interposer substrate, wherein a thermal conductive surface of the thermal conductive component is attached to the heat dissipation region of the connection surface of the at least one light valve, and the thermal conductive surface of the thermal conductive component is parallel to the connection surface; and
a flexible circuit board disposed on the interposer substrate and the thermal conductive component, wherein the interposer substrate is electrically connected to the flexible circuit board by the second surface; and
a lens module disposed on a transmission path of the image light beam and configured to project the image light beam outside the projection device.
